(19) United States
(12) Patent Application Publication
(10) Pub. No.: US 2005/0186515 A1
(43) Pub. Date: Aug. 25, 2005

(54) Structured materials and methods

(76) Inventor: James J. Watkins, South Hadley, MA (US)

Correspondence Address: FISH & RICHARDSON PC, 225 FRANKLIN ST, BOSTON, MA, 02110, US

(21) Appl. No.: 11/040,054

(22) Filed: Jan. 21, 2005

Related U.S. Application Data
(60) Provisional application No. 60/538,804, filed on Jan. 23, 2004.

(51) Int. Cl. G03F 7/00

(52) U.S. Cl. 430/322; 430/324; 430/323

(57) ABSTRACT

In general, in one aspect, the invention features methods for forming structured materials that include providing a layer including a first material; patterning the layer while a surface of the layer is exposed without the need for a processing layer, such as a resist; permeating the patterned layer with a precursor; and reacting the precursor within the patterned layer to form a structured material.

### CROSS-REFERENCE TO RELATED APPLICATIONS

This application claims priority under 35 U.S.C. §119 to Provisional Patent Application No. 60/538,804, entitled “STRUCTURED MATERIALS AND METHODS,” filed on Jan. 23, 2004, the entire contents of which is hereby incorporated by reference.

### FIELD OF THE INVENTION

This invention relates to structured materials and methods of making the same.

### BACKGROUND

Structured materials, such as those composed of silica and other metal oxides, ceramics, carbon and composite materials are of great interest for applications in numerous fields. For example, patterned substrates are used in MEMS (microelectromechanical systems), NEMS (nanoelectromechanical) systems, microfluidic devices, and implantable devices for biomedical applications. The characteristic feature size for these devices can range from less than about 10 nm to tens of microns or more. The structural material is often a metal oxide or ceramic, but can also include other materials, such as one or more metals or a composite material.

Currently, most structured materials are prepared by shaping a substrate composed of the desired material. For example, a silicon wafer can be patterned using a sequence of steps that include depositing a photoresist on the wafer, exposing and developing the photoresist, etching the exposed region of the wafer using conventional methods such as plasmas, and stripping the photoresist to recover the desired device structure. Alternatively, a structured material can be produced using micromachining or laser ablation.

### SUMMARY

In general, the invention features methods for forming patterned materials (also referred to as structured materials). A layer of structured material is formed by depositing a material within a patterned template. The deposited material adopts the template's pattern, providing the structured material. By selecting appropriate template materials and patterning techniques, a layer of template material can be patterned directly, without the need for additional processing layers (e.g., photoresists) and/or process steps. In other words, the layer of template material can be patterned while a surface of the layer is exposed and not covered with a processing layer. For example, a conventional approach to providing a patterned template would be to pattern a layer of the template material by depositing a layer of a resist on the layer of template material, exposing and developing the resist, etching the template material only in locations exposed by openings in the patterned resist, and removing the residual resist to provide the patterned template. In contrast, by selecting a template material that has the properties of a photoresist, one can pattern the template by exposing and developing the template itself, without the additional resist deposition, template etch, and resist removal steps. In other words, the template material can be patterned without covering the surface of the template material with a resist or other material. Accordingly, in certain aspects, the invention provides methods for efficiently providing patterned templates and structured materials.

After patterning, material is deposited by reacting a precursor within the template to form the structured material. The precursor can be delivered to the template in a supercritical or near supercritical solution (e.g., dissolved in a solvent that is under supercritical or near supercritical conditions). In such cases, the solution permeates the template, and on interaction with a reaction reagent and/or catalyst, and/or upon heating, the precursor chemically reacts and deposits a material within the template. After the reaction, the template material can be removed, while the deposited material remains intact, yielding a structured replica of the template composed of the deposited material. Alternatively, the template can be retained as part of the device structure.

Methods of structuring templates include photolithography, hot embossing, nanoimprint lithography, and step-and-flash lithography. In some embodiments, templates for three-dimensional structures can be prepared by two-photon lithography in a process called three-dimensional lithographic microfabrication. Other embodiments involve ordering the template by applying fields external to the template material, and using surface interactions to order the template material.

Template materials can be homogeneous or inhomogeneous. Typically, structured materials formed in homogeneous template materials are non-porous, while mesoporous materials can be formed using inhomogeneous template materials. Methods for forming mesoporous materials are described in U.S. Patent Application Publication No. 2003-0157248-A1, entitled “MESOPOROUS MATERIALS AND METHODS,” the entire contents of which is hereby incorporated by reference.

The invention also features uses of structured materials formed by the described methods. Potential applications of the materials are in the areas of Micro Electro Mechanical Systems (MEMS), Nano Electro Mechanical Systems (NEMS), microfluidic devices, medical implants, reactions, catalysis, environmental sensors, and molecular separations.

In general, in a first aspect, the invention features methods for forming structured materials that include providing a layer including a first material; patterning the layer while at least a portion of a surface of the layer is exposed, e.g., not covered with a processing layer (such as a resist), e.g., a substantial portion of the surface is not covered; permeating the patterned layer with a precursor, and reacting the precursor within the patterned layer to form a structured material.

Embodiments of the methods can include one or more of the following features and/or features of other aspects.

The layer can be patterned or structured by, for example, exposing the layer to radiation (e.g., visible or UV radiation). Exposing the layer to radiation can decompose portions of the first material. In some embodiments, exposing the layer to radiation crosslinks portions of the first material. The methods can include contacting the exposed surface of the layer with a master, e.g., to emboss a pattern into the layer, while exposing the layer to radiation, e.g., to cure or solidify the layer. The methods can include contacting the patterned layer with a master while permeating the patterned layer with a precursor. The layer can also be patterned by photolithography, step-and-flash lithography, or two-photon lithography. Patterning the layer can include imprinting the exposed surface with a pattern. The layer can also be patterned by hot embossing. Patterning the layer can further include etching portions of the layer after the imprinting. In other embodiments, the layer can be patterned by imprint lithography.

Permeating the patterned layer with a precursor can include permeating the patterned layer with a precursor delivery agent containing the precursor. The precursor delivery agent can be a supercritical or near-supercritical fluid.

The structured material can be a nonporous material or a porous (e.g., mesoporous) material.

The methods can include removing the first material after reacting the precursor within the patterned template. Removing the first material can include decomposing the first material and extracting decomposed material. Decomposing the first material can include heating the first material, exposing the first material to a solvent, or exposing the first material to radiation.

In some embodiments, the patterned layer can be exposed to radiation (e.g., UV, visible, or e-beam radiation). The patterned layer can be exposed to radiation before, after, or while permeating the patterned layer with a precursor.

The first material can be a homogeneous material or an inhomogeneous material. In some embodiments, the first material is a monomer or polymer (e.g., a homopolymer or a copolymer). The polymer can be a thermoplastic polymer or a thermoset polymer.

In another aspect, the invention features methods for forming structured materials that include providing a layer including a first material, patterning the layer, wherein the patterning includes exposing the layer of the first material to radiation, e.g., directly exposing the first material, without any additional process layer on top of the first material, permeating the patterned layer with a precursor, and reacting the precursor within the patterned layer to form a structured material. Embodiments of the methods can include one or more features of other aspects.

In a further aspect, the invention features methods for forming structured materials that include providing a layer including a first material, imprinting a surface of the layer with a pattern, permeating the layer with a precursor, and reacting the precursor within the layer to form a structured material. Embodiments of the methods can include one or more features of other aspects. Alternatively, or additionally, in some embodiments, imprinting the layer can include contacting the layer with a master. Patterning the layer can include etching portions of the layer after the imprinting.

The invention also features methods for forming structured materials that include forming a layer of a first material by surface photografting, permeating the layer with a precursor, and reacting the precursor within the template to form a structured material.

Embodiments of the methods can include one or more of the following features and/or features of other aspects. The layer of the first material can be a patterned layer. The surface photografting can include reacting a polymer with a substrate to form an anchored polymer layer. The surface photografting can include diffusing a monomer to a substrate surface. The substrate surface can include an initiating or propagating species.

In another embodiment, the invention features methods for forming structured materials that include providing a layer of a first material including a chiral moiety, permeating the layer with a precursor, and reacting the precursor within the layer to form a structured material. Embodiments of the methods can include one or more of the following features and/or features of other aspects. The first material can include a side-chain liquid crystal polymer. The structured material can include a biopolymer. The structured material can include a peptide or a protein.

In general, the structured materials can include features having a characteristic size from about 5 nm to 100 microns, e.g., about 10, 30, 50, 75, or 100 nm, or larger, e.g., 10, 30, 50, or 75 microns. In some embodiments, structured materials can be used in a photovoltaic device. In certain embodiments, structured materials formed using the above methods can be used in a high performance liquid chromatography (HPLC) column.

As used herein, a “supercritical solution” (or solvent or fluid) is one in which the temperature and pressure of the solution (or solvent or fluid) are greater than the respective critical temperature and pressure of the solution (or solvent or fluid). A supercritical condition for a particular solution (or solvent or fluid) refers to a condition in which the temperature and pressure are both respectively greater than the critical temperature and critical pressure of the particular solution (or solvent or fluid).

A “near-supercritical solution” (or solvent or fluid) is one in which the reduced temperature (actual temperature measured in Kelvin divided by the critical temperature of the solution (or solvent or fluid) measured in Kelvin) is greater than 0.8 and reduced pressure (actual pressure divided by critical pressure of the solution (or solvent or fluid)) of the solution (or solvent fluid) is greater than 0.5, but the solution (or solvent or fluid) is not a supercritical solution. A near-supercritical condition for a particular solution (or solvent or fluid) refers to a condition in which the reduced temperature is greater than 0.8 and reduced pressure is greater than 0.5, but the condition is not supercritical. Under ambient conditions, the solvent can be a gas or liquid. The term solvent is also meant to include a mixture of two or more different individual solvents.

Embodiments of the invention can provide one or more of the following advantages.

By decoupling the patterning of the template from the presence of deposition reagents, the new methods provide increased flexibility and efficiency. Additionally, the supercritical or near-supercritical solvent for the precursor does not dissolve the template, but only dilates it slightly. Thus, the template can be prepared in an independent step and the resulting composite material will retain the shape of the template.

Finally, the methods disclosed herein can be used for the rapid and efficient preparation of complex functional structures having a characteristic feature size that range from about 5 or 10 nm to more than a micron.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, and examples are illustrative only and not intended to be limiting.

Other features and advantages of the invention will be apparent from the following detailed description, and from the claims.

### DETAILED DESCRIPTION

General Methodology

Structured materials are typically prepared in two or more principal steps: (i) a suitable template having the desired structure is prepared; and (ii) the template is permeated with a precursor, which deposits a reaction product (or deposit) within the template. In some embodiments, the template is removed, leaving behind the structured material.

A patterned template can be prepared by a number of techniques including photolithography, hot embossing, nanoimprint lithography, step-and-flash lithography, two-photon lithography or by ordering a template material by applying fields external to the template material, and using surface interactions to order the template material. The template is formed from a material that can be patterned, e.g., using one of the aforementioned techniques, and which is compatible with the material to be deposited and the deposition technique (e.g., with the precursor, reaction product, and delivery agent).

In general, features of the patterned template can be on the order of about 5 nm to about 100 microns in size. In some embodiments, patterned templates can include structure that exhibits more than one characteristic size. For example, a template patterned on a microscopic scale (e.g., on a scale from about 100 nm to about 100 microns) can be formed from a material that has structure on a mesoscopic scale (e.g., on a scale from about 5 nm to about 100 nm). Examples of this include templates formed using materials with liquid crystalline phases (e.g., nematic, chiral nematic, smectic, and chiral smectic phases) that are patterned on microscopic scales using, for example, lithographic techniques.

In some embodiments, a catalyst, additive, or reagent is included in the template. Permeating the template layer with the precursor causes molecules of the precursor to diffuse into and through the template material. The catalyst/reagent sequestered within the template initiates a local condensation reaction of the precursor within the template, and a reaction product deposits within the template structure yielding a template/deposition product composite.

In some embodiments, the precursor is delivered using a delivery agent (e.g., in a solvent, that is a liquid, a supercritical fluid (SCF), or a near-SCF). For example, tetraethylorthosilicate (TEOS) dissolved in supercritical or near supercritical CO₂ can deposit silica within a suitable template. Additional reagents/catalysts necessary for deposition of the reaction product may be delivered with the precursor. Water is one example of a reagent that may be included in a supercritical or near supercritical CO₂ solution. The term “precursor mixture” refers to the precursor, precursor delivery agent, and any other components delivered with the precursor that assist in or enable the precursor to permeate the template, and/or enable the reaction product to deposit within the template.

In some embodiments, the template is removed after the deposition. Template removal may be accomplished by decomposition of the template material, (e.g., by calcination or exposure to other energy sources including UV radiation or plasmas).

Template Materials

Templates can be prepared from any material or combination of materials that can be patterned using one or more of the techniques discussed herein and include portions (e.g., domains) that are permeable to a desired precursor mixture, and that are compatible with the precursor condensation chemistry. Template materials can include organic materials (e.g., polymers, organic compounds, and assemblies of organic compounds) and inorganic materials (e.g., salts and clays).

Examples of template materials include homopolymers, block copolymers, random copolymers, polymer blends, and polymer composite materials. Block copolymers contain a linear arrangement of blocks, a block being a portion of a polymer molecule in which the monomeric units have at least one constitutional (e.g., the chemical makeup of the blocks) or configurational (e.g., the arrangement of atoms in the blocks) feature different from adjacent blocks. Under suitable conditions (e.g., within a favorable temperature and relative concentration range), some block copolymers self-assemble into domains of predominantly a single block type.

In some embodiments, the template is manipulated by the addition of fillers, metal clusters, nanoclusters and/or swelling agents. Additional examples of additives include quantum dots, magnetic clusters, catalytic metals, carbon nanotubes, and optically-active dyes.

Examples of template materials include homopolymers (e.g., amorphous or semi-crystalline homopolymers), hyperbranched polymers or blends of homopolymers and/or hyperbranched polymers and random copolymers. Examples of homopolymers include poly(methacrylic acid), poly(acrylic acid), polyethylene oxide, polycaprolactone, poly(lactic acids), polycarbonates, polysiloxanes, polyacrylates, poly(hydroxystyrene) and poly(vinyl alcohol). Examples of hyperbranched polymers include the aliphatic polyesters. Examples of copolymers include poly(methyl methacrylate-co-dimethyl amino ethyl methacrylate) and poly(methyl methacrylate)-co-poly(hydroxy styrene).

In some embodiments, the template material includes a homopolymer that phase separates from the material deposited within the template during or after the deposition process. This phase separation yields domains rich in the polymer template material and domains rich in the deposited material. Phase separation can be spinodal or binodal in nature. Phase separation may occur at any point during deposition of the deposited material (e.g., during reaction of the precursor within the template).

In some embodiments, a template may be composed of a homogeneous polymer matrix physically mixed with one or more other components that impart a desired property to the structured material. For example, the matrix polymer can be mixed with an additive, which alters the structure of the material produced using the matrix polymer. Examples of additives include metal or semiconductor nanoparticles, Polyhedral Oligomeric Silsesquioxane (POSS) compounds, salts, or other species different from the template material. The additives may be modified to improve compatibility with the template material (e.g., to improve mixing between the additive and template and/or to reduce phase separation of the additive and template material). Examples of chemical functionality that may improve compatibility include alkoxy and acetoxy groups.

In some embodiments, additives may be functionalized to provide covalent attachment to another moiety. Examples include functional groups that react to form covalent bonds. These can include groups that can undergo radical and condensation reactions (e.g., functional groups that can react include vinyl, alkoxy, acetoxy, hydroxy, and silane groups). In some embodiments, the functional groups may be introduced by copolymerization. In some embodiments, additives may be chiral (e.g., chiral salts or chiral liquid crystal polymers) and/or designed to impart specific chemical or biological recognition elements to the mesoporous material.

In some embodiments, templates can include a side chain liquid crystal polymer in which the side chains impart a mesogenic morphology. Examples include polysiloxane backbone side chain liquid crystal polymers and polyacrylate backbone side-chain liquid crystal polymers in which the side chain exhibits mesogenic behavior.

Chiral materials can be used to separate enantiomers of chiral molecules, such as organic chiral molecules (e.g., proteins or other biopolymers). In some embodiments, chiral templates can be prepared using, for example, side chain liquid crystal molecules. Infusion and reaction of a precursor in a chiral template followed by removal of the template can yield a structured material that is capable of performing such chiral separations. The resulting material is a chiral stationary phase (CSP) that can be used for enantiomer separations.

In some embodiments, a template can include a biopolymer, such as a peptide or protein. Examples of these templates include silicatein or peptide sequences including moieties such as lysine that act as a catalyst for reaction of the precursor. The template can include a protein or biopolymer that can be used for shape selective separations and/or separation of enantiomers. Templates can include one or more biopolymers in addition to a chiral moiety.

In general, the thickness and form of the template can be varied as desired. Template dimensions and shape often determine the dimension and shape of the structured material. In some embodiments, the templates are films less than one micrometer thick (e.g., less than 0.5, 0.3, or 0.1 micrometers). In alternative embodiments, template films are at least one micrometer thick (e.g., at least 2, 3, 5, or 10 micrometers). In general, templates are not limited to thin films. Bulk templates can also be used to prepare bulk structured materials (e.g., templates can be on the order of millimeters or centimeters thick).

A catalyst (or reaction reagent) can be incorporated into the template layer. A catalyst is often required to initiate the precipitation of the precursor onto the template. In some embodiments, the catalyst is sequestered preferentially in one region of the template, ensuring that precipitation occurs primarily within that region. In other embodiments, a catalyst that is activated by exposure to light or other forms of radiation is incorporated into the template. One example of such a catalyst is a photoacid generator. Examples of photoacid generators include perfluorooctyl sulfonate, diaryliodionium hexafluoroantimonate, diphenyliodonium 9,10-dimethoxyanthracenesulfonate isopropylthioxaanthone, [4-[(2 hydroxytetradecyl)oxy]phenyl] phenyliodonium hexafluoroantimonate, and triphenylsulfonium hexafluoroantimonate. The catalyst can then be activated in selected regions of the template by selective exposure. In another embodiment, an inhibitor to the reaction involving the precursor can be incorporated into selected regions of the template.

The catalyst can be included in the coating solution from which the template layer is cast, or it can be applied to the template layer in a separate process step. Often, the catalyst is a distinct chemical compound that does not react with the template. In some cases, the catalyst can be chemically incorporated into the template. In some cases, the template catalyses or promotes reaction of the precursor.

The chemical nature of the catalyst is determined primarily by the precursor material and nature of the desired precipitation reaction. Some acid catalysts, such as p-toluene sulfonic acid (PTSA), are suitable for initiating metal oxide condensation from their alkoxides (e.g., silica condensation from TEOS). Compatibility with the template, or at least a region of the template, is another factor in catalyst selection. PTSA is a suitable catalyst for use with many polymer templates. A non-limiting summary of metal oxide precursors and catalyst systems is available in Sol-Gel Science: The Physics and Chemistry of Sol-Gel Processing by C. J. Brinker and G W. Scherer (Academic Press, San Diego, Calif. (1989)).

Template Preparation and Patterning

Template layers can be prepared by first disposing a layer of template material onto a substrate. The substrate provides mechanical support for the template and the resulting structured material. Typically, the type of substrate will depend on the specific application of the structured material. For example, a silicon wafer can be used as a substrate for microelectronics applications. As another example, a porous substrate can serve as a supporting layer for a mesoporous membrane or other mesoporous separation medium. The substrate can be an integral part of a final product if the mesoporous film is part of a composite article (e.g., a microchip can include a mesoporous layer on a silicon wafer substrate). Suitable substrates include silicon wafers, glass sheets, polymer webs, silicon carbide, gallium nitride, and metal, metal oxide, or semiconductor layers deposited onto these substrates etc.

The template material(s) can be disposed on the substrate in a number of ways. Generally, the template is disposed on the substrate in a way that consistently yields a template layer having a desired thickness and composition. For example, the template material can be coated onto the substrate (e.g., spin-cast, knife-coated, bar-coated, gravure-coated, or dip-coated). The template material can be coated out of solution, and the solution evaporated to yield a layer of template material. The template material can also be evaporated onto a substrate. Alternatively, in some embodiments, the template material is self-supporting and no additional substrate is required.

Template layers can be patterned or ordered once the layer has been disposed on the substrate. For example, standard lithographic techniques (e.g., ultraviolet light or electron beam lithography) can be used to create a patterned template having three-dimensional structure.

In some embodiments, portions of the template material are directly exposed to radiation, resulting in a local change in the template structure and/or chemistry. One example is the exposure of a PMMA template to ultraviolet radiation. The ultraviolet radiation etches the PMMA, which can then be removed. Additionally, the ultraviolet radiation can be used to crosslink some polymers such as poly(hydroxystyrene). Light cross-linking can impart dimensional stability to the template during modification. High degrees of crosslinking can reduce the permeability and diffusion of precursors in a template. In some embodiments, regioselective crosslinking is used to suppress deposition in specific regions of the template.

In some embodiments, the template is coated with a standard photoresist, and the photoresist is selectively exposed to radiation. The photoresist is developed to expose portions of the underlying template, which are then etched away (e.g., wet etched or plasma etched). Removal of the residual photoresist yields a patterned template.

Selective exposure of the template material (or photoresist where it is additional to the template material) to radiation can be achieved in one or more of a variety of ways. For example, a radiation beam (e.g., an electron beam) focused to a spot can be rastered across the exposure surface. In another example, portions of the exposure surface are selectively masked from a blanket exposure to radiation using a shadow-mask. In a further example, the radiation forms an interference pattern, to which the template is exposed.

Typically, lithographic methods can be used to form channels, islands, and/or tiered relief structures in the template. The structures can be periodic or aperiodic. Structures can be on the scale of hundreds of microns to less than one micron in size (e.g., from about 100 nm, about 250 nm, about 500 nm and up to about one micron in size). A portion (or portions) of the template can be chemically crosslinked prior to or after the template has formed. Crosslinking can impart mechanical stability to the template, which may be advantageous, especially in embodiments where the template is likely to undergo additional processing (e.g., mechanical and/or chemical processing).

Patterned templates can also be formed by hot embossing. Typically, during a hot embossing process, a polymer substrate in imprinted using a master at elevated temperatures. A master refers to a work piece that can be repeatably used to impress a pattern into a material (i.e., the polymer substrate). The template retains the impression of the master after the template is removed. The polymer substrate is usually a thermoplastic or thermoset polymer. In some embodiments, the template contains a mixture of thermoplastic and thermosetting polymers. In some embodiments, the polymer is cross-linked thermally or by means of exposure to radiation during embossing. Examples of hot-embossing are described by Y. J. Juang and co-workers in Polymer Engineering and Science 2002, vol. 42, pp. 539-550, 2002, and by S. Z. Qi and co-workers in Lab on a Chip, vol. 2, pp. 88-95, 2002.

Templates can also be patterned by imprint or nanoimprint lithography. In imprint lithography, a mold with the desired features is pressed into a thin polymer resist cast on a substrate, which creates a thickness contrast pattern in the resist. After the mold is removed, an anisotropic etching process can be used to transfer the pattern into the entire resist thickness. One example of a resist is poly(methylmethacrylate), although a wide variety of polymers can be used (see, e.g., Chou et al., Science, vol. 272, p. 85, 1996). A variant of nanoimprint lithography is roller nanoimprint lithography, in which a cylindrical master is rolled across the polymer resist (see, e.g., Tan et al., J. Vac. Sci. Tech. B., vol. 16, p. 3926, 1998). Another embodiment of nanoimprint lithography, called “step and flash” lithography, uses a transparent master containing the pattern to be printed etched into its surface. A photocurable monomer solution is dispensed onto a substrate in the region where the pattern is desired. The master is then brought into contact with the substrate to spread the monomer solution. UV light is then irradiated through the back of the master, curing the monomer and leaving the cured template behind. Step and flash lithography is described, for example, by D. J. Resnick and co-workers in Microelectronic Engineering, vol. 69, p. 412, 2003.

In some embodiments, templates can be formed by three-dimensional lithographic microfabrication (3-DLM) using two-photon lithography (Zhou et al., Science, vol. 296, p. 1106, 2002; Yu et al., Adv. Mater., vol. 15, p. 517, 2003). Use of a two-photon acid generator in conjunction with a chemically amplified resist provides a means for direct writing of three dimensional polymer structures. A chemically amplified resist is a type of photoresist where the exposure reaction initiates a chain reaction of chemical events. Chemically amplified photoresists are typically more sensitive than standard photoresist and are widely used for DUV exposure. A number of resist systems can be used including random copolymers of tetrahydropyranylmethacrylate (THPMA), methyl methacrylate (MMA), and tert-butyl methacrylate (tBMA). In the presence of a strong acid generated by an appropriate photoacid generator, a deprotection reaction generates poly(methacrylic acid) by cleavage of tetrahydropyranyl (THP) and tert-butyl protecting groups. The polarity change provides a means for developing the resist to obtain a 3-D structured template. For example, aqueous base can be used to remove the acidic copolymer from the exposed regions or organic solvent can be used to remove the unexposed regions. The template is composed of the remaining structure. In some embodiments, the template can be exposed to light after development to generate acid in the patterned template.

The template can also be formed by surface photografting. Photografting can include “grafting to” and “grafting from” a surface. In the “grafting to” approach, functionalized polymers are reacted with a solid surface to form an anchored polymer layer. In the “grafting from” approach, monomer diffuses to initiating and/or propagating species that are present on the substrate surface. Surface initiation can be combined with living radical polymerization techniques to control the thickness of the layer. These techniques can include nitroxide-mediated polymerization, photo-initiator-controlled polymerization and/or atom transfer radical polymerization. Examples of surface photografting are described by Luo and co-workers in Macromolecules, vol. 36, pp. 6739-6745, 2003. In some embodiments, the initiating site is tethered or bound to the substrate surface. The initiating/propagating sites on the substrate can be disposed in a pattern. The pattern can be created by exposure to light or by surface modification of the substrate. The initiator molecules can also be anchored and patterned using self-assembled monolayers.

In some embodiments, the template is infused in the presence of a mold or master. For example, a block copolymer template can be spin-coated onto a wafer (e.g., a Si wafer). The template can then be patterned by hot embossing, and can be infused with the precursor while maintaining contact between the master and the template. Such contact may improve the dimensional stability of the imprinted feature during infusion. In some embodiments, the mold or master can contain perforations or open spaces to improve contact between the supercritical fluid and the template. For example, the master may contain open spaces above regions of the template that are not embossed. Similarly, in some embodiments, the template is prepared by step and flash lithography and the master remains in contact with the template during infusion of the precursor with a supercritical fluid.

Precursor Delivery into Templates

In general, any means by which to permeate the template with the precursor that does not detrimentally alter the template morphology, or detrimentally affect the deposition chemistry, can be employed. Generally, the precursor is delivered by way of a delivery agent, e.g., in a solvent. For example, the precursor can be dissolved in a supercritical or near supercritical fluid. The SCF or near SCF solution is then infused into the template, and the precursor reacts with a reagent/catalyst partitioned in one or more of the template domains.

In the discussion that follows, precursor delivery in both batch and continuous mode is described by way of example. A typical batch run in which a precursor in a SCF solution is delivered to a template layer involves the following general procedure. A single substrate and a known mass of precursor are placed in a reaction vessel (e.g., a stainless steel pipe), which is sealed, purged with solvent, weighed, and immersed in a circulating, controlled temperature bath. The vessel is then filled with solvent, containing a known amount of precursor, e.g., using a high-pressure manifold. The contents of the reactor are brought to a specified temperature and pressure at which the solvent is a supercritical or near-supercritical solvent. The solution permeates the template. The precursor dissolved in the solvent interacts with the catalyst or other reagent, which is preferentially sequestered in specific domains within the template. The precursor reacts within the template in these domains. The vessel is maintained at this condition for a period of time sufficient to ensure that the solution has completely penetrated into the template and that the precursor has reacted, precipitating a reaction product onto or into the template. The reaction is typically carried out for at least one hour, though the reaction can be complete at times much less than one hour, e.g., less than 20 minutes or even less than 30 seconds. The optimal length of reaction time can be determined empirically. When the reactor has cooled, the substrate is removed and can be analyzed or further treated to remove the template.

A continuous precursor delivery process is similar to the above batch method except that known concentrations of the supercritical (or near-supercritical) solution are taken from a reservoir and continuously added to a reaction vessel containing multiple substrates as supercritical solution containing precursor decomposition products or unused reactants is continuously removed from the reaction vessel. The flow rates into and out of the reaction vessel are made equal so that the pressure within the reaction vessel remains substantially constant. The overall flow rate is optimized according to the particular reaction. Prior to introducing precursor-containing solution into the reaction vessel, the reaction vessel is filled with neat solvent (which is the same as the solvent in the precursor solution) at supercritical or near-supercritical pressures and is heated to supercritical or near-supercritical temperatures. As a result, supercritical or near-supercritical conditions are maintained as the precursor-containing solution is initially added to the reaction vessel.

Solubility of the precursor at the reaction conditions can be verified in a variable volume view cell, which is well known in the art (see, for example, McHugh et al., Supercritical Fluid Extraction: Principles and Practice, Butterworths, Boston, 1986). Known quantities of precursor and supercritical solvent are loaded into the view cell, where they are heated and compressed to conditions at which a single phase is observed optically. Pressure is then reduced isothermally in small increments until phase separation (either liquid-vapor or solid-vapor) is induced.

The temperature and pressure of the process depend on the precursor, reaction reagent(s), and choice of solvent. Generally, temperature is less than 250° C. and often less than 100° C. (e.g., less than about 90° C., 80° C., 70° C., 60° C., 50° C., or 40° C.), while the pressure is typically between 50 and 500 bar (e.g., between about 75 bar and 300 bar, 90 bar and 200 bar, 100 bar and 150 bar, 110 bar and 140 bar, or 120 bar and 130 bar). A temperature gradient between the substrate and solution can also be used to enhance chemical selectivity and to promote reactions within the template.

Solvents useful as SCFs are well known in the art and are sometimes referred to as dense gases (Sonntag et al., Introduction to Thermodynamics, Classical and Statistical, 2nd ed., John Wiley & Sons, 1982, p. 40). At temperatures and pressures above certain values for a particular substance (defined as the critical temperature and critical pressure, respectively), saturated liquid and saturated vapor states are identical and the substance is referred to as a SCF. Solvents that are SCFs are less viscous than liquid solvents by one to two orders of magnitude. The low viscosity of the supercritical solvent and absence of surface tension facilitates improved transport (relative to liquid solvents) of precursor to, and decomposition products away from, the template. This is particularly advantageous in ensuring complete permeation of the template layer by the solution. Furthermore, the solubility of many precursors increases in supercritical solvents, relative to various liquids and gases. Generally, a supercritical solvent can be composed of a single solvent or a mixture of solvents, including for example a small amount (<5 mol percent) of a polar liquid co-solvent such as ethanol (or other alcohol).

It is desirable that the precursors are sufficiently soluble in the supercritical solvent to allow homogeneous transport of the reagents. Solubility in a supercritical solvent is generally proportional to the density of the supercritical solvent. Ideal conditions for precursor transport include a supercritical solvent density of at least 0.1 to 0.2 g/cm³ or a density that is at least one third of the critical density (the density of the fluid at the critical temperature and critical pressure).

Table 1 below lists some examples of solvents along with their respective critical properties. These solvents can be used by themselves or in conjunction with other solvents to form the supercritical solvent. Table 1 lists the critical temperature, critical pressure, critical volume, molecular weight, and critical density for each of the solvents.

TABLE 1
CRITICAL PROPERTIES OF SELECTED SOLVENTS

| | T_{c} | P_{c} | V_{c} | Molecular | ρ_{c} |
|---|---|---|---|---|---|
| Solvent | (K) | (atm) | (cm/mol) | Weight | (g/cm³) |
| CO₂ | 304.2 | 72.8 | 94.0 | 44.01 | 0.47 |
| C₂H₆ | 305.4 | 48.2 | 148 | 30.07 | 0.20 |
| C₃H₈ | 369.8 | 41.9 | 203 | 44.10 | 0.22 |
| n-C₄H₁₀ | 425.2 | 37.5 | 255 | 58.12 | 0.23 |
| n-C₅H₁₂ | 469.6 | 33.3 | 304 | 72.15 | 0.24 |
| CH₃—O—CH₃ | 400 | 53.0 | 178 | 46.07 | 0.26 |
| CH₃CH₂OH | 516.2 | 63.0 | 167 | 46.07 | 0.28 |
| H₂0 | 647.3 | 12.8 | 65.0 | 18.02 | 0.33 |
| C₂F₆ | 292.8 | 30.4 | 22.4 | 138.01 | 0.61 |

To describe conditions for different supercritical solvents, the terms “reduced temperature,” “reduced pressure,” and “reduced density” are used. Reduced temperature, with respect to a particular solvent, is temperature (measured in Kelvin) divided by the critical temperature (measured in Kelvin) of the particular solvent, with analogous definitions for reduced pressure and density. For example, at 333 K and 150 atm, the density of CO₂ is 0.60 g/cm³; therefore, with respect to CO₂, the reduced temperature is 1.09, the reduced pressure is 2.06, and the reduced density is 1.28. Many of the properties of supercritical solvents are also exhibited by near-supercritical solvents, which refers to solvents having a reduced temperature and a reduced pressure greater than 0.8 and 0.6, respectively, but not both greater than 1 (in which case the solvent would be supercritical). One set of suitable conditions for template infusion include a reduced temperature of the supercritical or near-supercritical solvent of between 0.8 and 1.6 and a critical temperature of the fluid of less than 150° C.

Carbon dioxide (CO₂) is a particularly good choice of solvent. Its critical temperature (31.1° C.) is close to ambient temperature and thus allows the use of moderate process temperatures (<80° C.). It is also unreactive with many desirable precursors and is an ideal media for running reactions between gases and soluble liquids or solid substrates.

Precursors and Reaction Mechanisms

Precursors are chosen so that they yield a desired deposit material in the template following reaction facilitated by the catalyst (or reaction reagent). Deposits can include oxides (e.g., oxides of metals, such as Si, Zr, Ti, Al, and V), or mixed metal or mixed metal oxides (e.g., or a superconducting mixture such as Y—Ba—Cu—O), metals (e.g., Cu, Pt, Pd, and Ti), elemental semiconductors (e.g., Si, Ge, and C), compound semiconductors (e.g., III-V semiconductors such as GaAs and InP, II-VI semiconductors such as CdS, and IV-VI semiconductors such as PbS). Precursors for oxide deposition include alkoxides, such as TEOS for silica deposition. Deposits can also include halogenated compounds (e.g., a fluorinated, chlorinated, brominated or iodinated compounds).

In some embodiments, the precursor is a monomer or mixture of monomers and the deposited material is a polymer or a mixture of polymers. In such cases, the deposited polymer can exhibit a decomposition temperature substantially above the decomposition temperature of the template material (e.g., a template polymer). Once the high temperature polymer is deposited, the template polymer can be removed. A catalyst for monomer polymerization can optionally be deposited within the template or the template material may possess chemical functionality such as acid groups that catalyses the polymerization. Non-limiting examples of polymers with high decomposition temperatures (e.g., greater than about 450° C. or 500° C., such as 550° C. or more) include aromatic polymers, such as polyphenylenes.

In some embodiments, the precursor includes a B-staged organo polysilica dielectric matrix material. B-staged refers to uncured materials. In other words, under appropriate conditions, a B-staged organo polysilica material can be polymerized or cured, such as by condensation, to form higher molecular weight materials, such as coatings or films. Such B-staged material may be monomeric, oligomeric or mixtures thereof. B-staged material is further intended to include mixtures of polymeric material with monomers, oligomers or a mixture of monomers and oligomers.

In general, any reaction yielding the desired material from the precursor can be used. Naturally, the precursors and reaction mechanisms should be compatible with the chosen method of precursor delivery to the template. For example, when utilizing SCF or near SCF solutions low process temperatures (e.g., less than 250° C., 200° C., 150° C., or 100° C. for CO₂) and relatively high fluid densities (e.g., greater than 0.2 g/cm³ for CO₂) in the vicinity of the template are important features. If the template temperature is too high, the density of the fluid in the vicinity of the substrate approaches the density of a gas, and the benefits of the solution-based process are lost. In addition, a high template temperature can adversely affect template morphology. For example, the reaction can involve reduction of the precursor (e.g., by using H₂ or H₂S as a reducing agent), oxidation of the precursor (e.g., by using O₂ or N₂O as an oxidizing agent), or hydrolysis of the precursor (i.e., adding H₂O). An example of a hydrolysis reaction is water (the reaction reagent) reacting with a metal alkoxide (the precursor), such as titanium tetraisopropoxide (TTIP), to produce a metal oxide structure, such as TiO₂. The reaction can also be initiated by optical radiation (e.g., photolysis by ultraviolet light). In this case, photons from the optical radiation are the reaction reagent. In some embodiments, the precursor can thermally disassociate to yield the deposit.

In some cases, the precursor delivery agent can participate in the reaction. For example, in a supercritical solution including N₂O as an additional solvent and metal precursors such as organometallic compounds, N₂O can serve as an oxidizing agent for the metal precursors yielding metal oxides as the desired material. In most cases, however, the solvent in the SCF is chemically inert.

Post-Synthesis Treatment

The product that results from delivering the precursor into the template and reacting the precursor is a composite (e.g., film or bulk layer) of the template material and the reaction product. The template material can be removed to yield a structured product. In such cases, the template material is usually decomposed, using one or more of a number of techniques. For example, a polymer template can be decomposed thermally, by calcination. Template removal from silica-polymer composites is well suited to calcination, as the decomposition temperature of most polymers (e.g., about 400° C.) will not affect the silica structure. Alternatively, the template can be decomposed or dissolved by chemical or photochemical techniques. The composite layer can be exposed to solvents or etchants and/or reactive plasmas that decompose the template. Photochemical techniques include the decomposition of the template by exposure to the appropriate radiation (e.g., ultraviolet radiation).

Decomposition of the template material can be performed in the presence of a fluid to facilitate template removal. In some cases, the precursor delivery agent can provide this function. For example, supercritical or near-supercritical CO₂ or CO₂/O₂ mixtures can exploit the transport advantages of SCFs in materials to expedite removal of the decomposed template.

In some cases, further reaction or curing of the deposited phase may be effected by irradiating the deposit with light (e.g., visible or UV light) or electron beams. Such radiation can be applied before or after removal of the template to promote additional reaction. The light or e-beam cure can be applied, for example, to silicate or organosilicate films. Examples of radiation sources include UV radiation tools, such as PCUP, manufactured by Axcelis (Rockville, Md.). E-beam radiation can be produced using e-beam tools, such as the ElectronCure™ tool, manufactured by Electron Vision Group.

After template removal, the layer of deposited material can be further treated as desired. In many cases, this can be achieved using SCF CO₂ solutions of reagents. These reactions can include the use of commercial organosilane coupling agents including mono, di, and trifunctional coupling agents, such as those described in C. J. Brinker and G. W. Scherer, Sol-Gel Science: the Physics and Chemistry of Sol-Gel Processing, Academic Press, San Diego Calif., 1999, p. 662.

Further treatment of the material can also be performed in the presence the precursor delivery agent, e.g., in the presence of a supercritical or near-supercritical fluid mixture (e.g., CO₂ or CO₂/O₂), thereby exploiting the transport advantages of SCFs in materials.

In some embodiments, a precursor is infused into the template, a reaction product is deposited within the template and the template/reaction product composite is processed further prior to removal of the template. In these embodiments, the presence of the template can impart beneficial mechanical properties for subsequent processing. For example, the template/reaction product composite can be further patterned and etched prior to removal of the template to incorporate device structures. The template/reaction product composite can be etched to incorporate device features, materials can be deposited within those features and the deposited material can be planarized prior to removal of the template.

In general, structured materials can be used in a variety of applications, such as, for example, in semiconductor, MEMS, NEMS, optical, and microfluidic devices. In some applications, structured materials can be used for High Performance Liquid Chromatography (HPLC). For example, chiral structured materials can be used in columns for separating molecular enantiomers (e.g., enantiomers of acids, amines, alcohols, amides, esters, sulfoxides, carbamates, ureas, amino alcohols, succinamides, hydantoins, binaphtols, beta-lactams, cyclic drugs, aromatic drugs, lactones, cyclic ketones, alkaloids, dihydropyridines, oxazolindones, and/or Non Steroidal Anti-Inflammatory Drugs (NSAIDS)). In certain embodiments, chiral structured materials can be used in Pirkle Chiral Stationary Phase (CSP) columns, which are described, for example, in “Practical HPLC Method Development,” 2nd Edition, by L. R. Snyder et al. (John Wiley & Sons, New York, N.Y., 1997).

In some embodiments, structured materials, such as structured titania (TiO₂), can be used in photovoltaic devices. These devices can be made by assembling layers of titania, which is a light-sensitive dye, an electrolyte and a catalyst between two transparent conductive plates (e.g., plastic or glass plates). The conductive plates function as electrodes. When light shines on the cell, the dye is energized and releases electrons that are picked up by the titania. The electrolyte regenerates the dye after it gives off its charge, while the catalyst supplies the electron to the electrolyte. When a load is attached across the electrodes, the absorbed light is converted into a DC current across the load.

### EXAMPLES

The invention is further described in the following examples, which do not limit the scope of the invention described in the claims.

### Example 1

### Preparing a Patterned Silica Film Using a Patterned Random Copolymer Template

A silicon wafer is cleaned in a mixture of ammonium hydroxide, deionized water and hydrogen peroxide (6:1:1 parts by volume), rinsed in deionized water, cleaned in a second solution of HCl, deionized water and hydrogen peroxide (6:1:1 parts by volume) and then rinsed in deionized water. A thin film of a poly(hydroxystyrene)-co-poly(methyl methacrylate) is spin-cast onto cleaned silicon substrates from a solution containing a small amount of p-toluene sulfonic acid (PTSA) and water. After drying, a suitable lithographic mask is placed onto the substrate supported copolymer film. The film and mask are then exposed to ultraviolet radiation. The mask is removed and the low molecular weight decomposition products are extracted from the polymer films by solvent washing. The patterned film is then placed into a high-pressure reactor. The reactor is constructed from opposed stainless steel blind hubs sealed with a metal seal ring (obtained from Grayloc Products, Houston, Tex.). Machined ports are present on the blind hubs for introducing and venting of CO₂ and for monitoring the pressure and temperature inside the reactor. A rupture disc assembly, with a pressure rating below that of the reactor, is also present on the reactor for safety purposes. The temperature in the reactor is maintained constant using external band heaters (obtained from Watlow, Merrimack, N.H.). The reactor is sealed and the film is exposed to 5 microliters of tetraethylorthosilicate (TEOS) in humidified carbon dioxide at 122 bar for 2 hours using a high pressure syringe pump (ISCO, Inc) that is maintained at 60° C. using a constant temperature bath. The inner temperature of the reactor is measured using an inner thermocouple and is maintained to ±2° C. using a combination of an externally mounted thermocouple and a temperature controller, which uses external band heaters (obtained from Watlow) to heat the outer walls. The reactor is then slowly vented to atmospheric pressure. The composite film is removed from the reactor. The polymer template is then removed by calcination at 400° C. in an oven yielding a patterned silica film.

### Example 2

### Using a Patterned Negative Tone Random Copolymer Resist as a Template

A silicon wafer is cleaned. The wafer is then pre-treated by exposure to 1,1,1,3,3,3-hexamethydisilazane or by coating with an anti-reflective coating. A thin film of a negative tone random copolymer photoresist (a random copolymer of tetrahydropyranylmethacrylate (THPMA), methyl methacrylate (MMA) and tert-butyl methacrylate (tBMA)) is disposed onto the wafer. The resist is spin-cast onto the wafer from a solution containing a photoacid generator. In the presence of a strong acid generated by the photoacid generator, a deprotection reaction generates poly(methacrylic acid) by cleavage of THP and tert-butyl protecting groups. The resist is then developed using a suitable solvent, leaving the patterned poly(methacrylic acid) containing copolymer on the wafer. The patterned film is then placed into a high-pressure reactor similar to that described in Example 1. The reactor is sealed and the film is exposed to a 0.1 percent solution of TEOS in humidified CO₂ at 60° C. and 125 bar for 3 hours. The reactor is then slowly vented to atmospheric pressure. The composite film is then removed from the reactor. The polymer template is then removed by calcination at 400° C. in an oven yielding a patterned silica film on the wafer.

### Example 3

### Preparation of a Structured Material Using a Template Prepared by Imprint Photolithography

A silicon wafer is cleaned and an organic planarization layer is spin-coated onto the wafer. A template is prepared using nanoimprint photolithography in a manner similar to that described by Colburn et al. (J. Vac. Sci. Technol. B, vol. 19, no. 6, p. 2685, 2001). A solution of butyl acrylate, ethylene glycol dimethacrylate, poly(ethylene glycol) mono methacrylate, a photo iniferter (Irgacure 651) and p-toluene sulfuric acid is dispensed on the wafer. A transparent master is pressed into the monomer solution. The master is illuminated by a U.V. lamp, causing polymerization of the monomer solution. The master is removed, leaving a solid replica on the substrate surface. An etch process is used to remove residue between the features. The replica is used as the template for the structured material. The substrate containing the replica is transferred to a high pressure reactor similar to that described in Example 1. The reactor is sealed and the film is exposed to a 0.1 percent solution of TEOS and methyltriethoxysilane in humidified CO₂ at 60° C. and 125 bar for 3 hours. The reactor is then slowly vented to atmospheric pressure. The composite film is then removed from the reactor. The polymer template is then removed by calcination at 400° C. in an oven yielding a patterned silicate film on the wafer.

### Example 4

### Using a Patterned Template Containing Si Prepared by Imprint Photolithography

A silicon wafer is cleaned and pre-treated by coating with an anti-reflective coating. A solution of butyl acrylate, (3-acryloxypropyl)tris(trimethylsiloxy)silane, 1,3 bis(3-methacryloxypropyl)tetramethyldisiloxane, a photo inifter (Irgacure 651) and a small amount of p-toluene sulfonic acid (PTSA) is dispensed onto the wafer. A transparent master is pressed into the monomer solution. The master is illuminated by a UV lamp, causing polymerization of the monomer solution. The master is removed leaving a solid replica of the master on the substrate surface. An etch process is used to remove residual polymer between the features. The replica is then used as the template for the structured material. The patterned template is then placed into a high-pressure reactor similar to that described in Example 1. The reactor is sealed and the film is exposed to a 0.1 percent solution of TEOS in humidified CO₂ at 60° C. and 125 bar for 3 hours. The reactor is then slowly vented to atmospheric pressure. The composite film is then removed from the reactor. The polymer template is then removed by calcination at 400° C. in an oven yielding a patterned silica film on the wafer.

### Example 5

### Using a Patterned Template Containing Reactive Functionality that can React with the Precursor Prepared by Imprint Photolithography

A silicon wafer is cleaned. The wafer is then pre-treated by coating with an anti-reflective coating. A solution of butyl acrylate, (3-acryloxypropyl)trimethoxysilane 1,3 bis(3-methacryloxypropyl)tetramethyldisiloxane, a photo iniferter (Irgacure 651) and a small amount of a suitable photoacid generator is dispensed onto the wafer. A transparent master is pressed into the monomer solution. The master is illuminated by a 365 nm UV lamp, causing polymerization of the monomer solution. The master is removed leaving a solid replica of the master on the substrate surface. An etch process is used to remove residual polymer between the features. The replica is then used as the template for the structured material. The patterned template is then exposed to light of a suitable wavelength to activate the photoacid generator and is placed into a high-pressure reactor similar to that described in Example 1. The reactor is sealed and the film is exposed to a 0.1 percent solution of TEOS in humidified CO₂ at 60° C. and 125 bar for 3 hours. The reactor is then slowly vented to atmospheric pressure. The composite film is then removed from the reactor. The polymer template is then removed by calcination at 400° C. in an oven yielding a patterned silica film on the wafer.

### Example 6

### Using a Patterned Template Prepared by Hot Embossing

A random copolymer of poly(ethylene oxide) and poly(hydroxystyrene) is spin cast on a silicon wafer. The polymer film is imprinted with a master (mold) at a temperature above the glass transition temperature of the copolymer. With the mold in place, the film is cooled below the glass transition temperature of the copolymer. The mold is removed and the copolymer is lightly cross-linked by exposure to UV irradiation. The patterned film is then placed into a high-pressure reactor similar to that described in Example 1. The reactor is sealed and the film is exposed to a 0.1 percent solution of TEOS in humidified CO₂ at 90° C. and 125 bar for 3 hours. The reactor is then slowly vented to atmospheric pressure. The composite film is then removed from the reactor. The polymer template is then removed by calcination at 400° C. in an oven yielding a patterned silica film on the wafer.

### Example 7

### Using a Patterned Template Prepared by Hot Embossing to Prepare Structured Titania

A random copolymer of poly(ethylene oxide) and poly(hydroxystyrene) is spin cast on a conducting glass substrate. The polymer film is imprinted with a master (mold) at a temperature above the glass transition temperature of the copolymer. With the mold in place, the film is cooled below the glass transition temperature of the copolymer. The mold is removed and the copolymer is lightly cross-linked by exposure to UV irradiation. The patterned film is then placed into a high-pressure reactor similar to that described in Example 1. The reactor is sealed and the film is exposed to a 0.1 percent solution of titanium diisopropoxide bis(acetylacetonate) at 130 bar and 60° C. in CO₂ for 3 hours. The reactor is then slowly vented to atmospheric pressure. The composite film is then removed from the reactor. The polymer template is then removed by calcination at 400° C. in an oven yielding a patterned titania film on the substrate.

### Example 8

### Using a Patterned Template Prepared by Imprint Lithography Followed by UV Curing

A lightly cross-linked copolymer film of poly(methacrylic acid) and poly(methylmethacrylate) is prepared on a silicon wafer. The polymer film is imprinted with a master (mold) at a temperature above the glass transition temperature of the copolymer. With the mold in place, the polymer film is cooled below the glass transition temperature. After imprinting, oxygen reactive ion etching transfers the pattern through the entire resist thickness. The patterned film is then placed into a high-pressure reactor similar to that described in Example 1. The reactor is sealed and the film is exposed to a 0.1 percent solution of TEOS in humidified CO₂ at 90° C. and 125 bar for 3 hours. The reactor is then slowly vented to atmospheric pressure. The composite film is then removed from the reactor and exposed to UV radiation to degrade the template and promote curing of the silica network. The remaining polymer template is then removed by calcination at 400° C. in an oven yielding a patterned silica film on the wafer.

### Example 9

### Using a Patterned Template Prepared by Imprint Lithography followed by E-Beam Curing

A lightly cross-linked copolymer film of poly(methacrylic acid) and poly(methylmethacrylate) is prepared on a silicon wafer. The polymer film is imprinted with a master (mold) at a temperature above the glass transition temperature of the copolymer. With the mold in place, the polymer film is cooled below the glass transition temperature. The patterned film is then placed into a high-pressure reactor similar to that described in Example 1. The reactor is sealed and the film is exposed to a 0.1 percent solution of methyltriethoxysilane in humidified CO₂ at 90° C. and 125 bar for 3 hours. The reactor is then slowly vented to atmospheric pressure. The composite film is then removed from the reactor and exposed to e-beam radiation to promote curing of the silicate network. The remaining polymer template is then removed by calcination at 400° C. in an oven yielding a patterned silica film on the wafer.

### Example 10

### Using Templates Prepared by Two-Photon 3-D Lithographic Micro Fabrication

A template is prepared using two-photon lithographic micro fabrication using a process similar to that described by Yu et al. (Adv. Mater., vol. 15, no. 6, p. 517, 2003). In this process, a two photon acid generator is blended with a resist prepared by the copolymerization of tetrahydropyranyl methacrylate, methyl methacrylate and tert-butyl methacrylate. The resist blend is dispensed onto a silicon wafer, forming a 50 μm thick film. 3-D micro fabrication is carried out by exposing the film to pulses from a Ti:sapphire laser in the 3-D pattern of the target structure on a translating stage. After exposure, the film is baked and developed to remove the unexposed regions. The resulting 3-D structure is then used as the template for the structured material. The 3-D structure is then placed into a high-pressure reactor similar to that described in Example 1. The reactor is sealed and the film is exposed to a 0.1 percent solution of TEOS in humidified CO₂ at 90° C. and 125 bar for 3 hours. The reactor is then slowly vented to atmospheric pressure. The polymer template is then removed by calcination at 400° C. in an oven.

### Example 11

### Using a Template Prepared by Photografting Polymerization on a Polymer Substrate Using an Iniferter

A N,N-Diethyldithiocarbamated polymer substrate is prepared using a method similar to that described by Luo et al. (Macromolecules, vol. 36, p. 6739, 2003). A solution of hexyl methacrylate, 1,2-dodecyl dimethacrylate, (methacryloylethylene-dioxycarbonyl) benzyl N,N-diethyldithio carbamate (HEMA-E-I), benzoyl peroxide and N,N-dimethylaniline is polymerized thermally at 50° C. in a glass mold. A patterned template is then prepared on the surface by spreading a solution of poly(ethylene glycol) methacrylate and methoxylpoly(ethylene glycol) methacrylate and p-toluene sulfuric acid between glass spacers, covering the solution with a cover glass and a photo-mask and irradiating the surface with UV light. After irradiation the surface is rinsed with distilled water and acetone. The patterned film is then placed into a high-pressure reactor similar to that described in Example 1. The reactor is sealed and the film is exposed to a 0.1 percent solution of methyltriethoxysilane in humidified CO₂ at 90° C. and 125 bar for 3 hours. The reactor is then slowly vented to atmospheric pressure. The composite film is then removed from the reactor and exposed to e-beam radiation to promote curing of the silicate network. The remaining polymer template is then removed by calcination at 400° C. in an oven yielding a patterned silica film on the wafer.

### Example 12

### Using a Template Comprised of a Patterned Gel Prepared by Photografting Polymerization on a Polymer Substrate Using an Iniferter and the Polymer Substrate

A N,N-Diethyldithiocarbamated polymer substrate is prepared by using a method similar to that described by in Example 10. A solution of hexyl methacrylate, 1,2-dodecyl dimethacrylate, poly(ethylene glycol) methacrylate, (methacryloylethylene-dioxycarbonyl) benzyl N,N-diethyldithio carbamate (HEMA-E-I), benzoyl peroxide, N,N-dimethylaniline and an organic acid such as p-toluene sulfonoc acid is polymerized thermally at 50° C. in a glass mold. A patterned template is then prepared on the surface by spreading a solution of poly(ethylene glycol) methacrylate and methoxylpoly(ethylene glycol) methacrylate and p-toluene sulfinuric acid between glass spacers, covering the solution with a cover glass and a photo-mask and irradiating the surface with UV light. After irradiation, the surface is rinsed with distilled water and acetone. The patterned film on the substrate is then placed into a high-pressure reactor similar to that described in Example 1. The reactor is sealed and the film is exposed to a 0.1 percent solution of methyltriethoxysilane in humidified CO₂ at 90° C. and 125 bar for 3 hours. Condensation of methyltriethoxysilane occurs within the patterned template and within the substrate polymer. The reactor is then slowly vented to atmospheric pressure. The composite film is then removed from the reactor and exposed to e-beam radiation to promote curing of the silicate network. The remaining polymer template is then removed by calcination at 400° C. in an oven yielding a structured material.

### Example 13

### Using a Biodegradable Template Prepared by Injection Molding

A sample of poly(DL-lactide) containing a small amount of organic acid is prepared by injection molding to form a template for the structured material. The template is placed into a high-pressure reactor similar to that described in Example 1. The reactor is sealed and the film is exposed to a 0.1 percent solution of TEOS in humidified CO₂ at 90° C. and 125 bar for 3 hours. The reactor is then slowly vented to atmospheric pressure. The composite is then removed from the reactor.

### Example 14

### Using a Biodegradable Template Containing Hydroxyapatite Prepared by Injection Molding

A sample of polycaprolactone blended with hydroxyapatite powder and a small amount of organic acid is prepared by injection molding to form a template for the structured material. The template is placed into a high-pressure reactor similar to that described in Example 1. The reactor is sealed and the film is exposed to a 0.1 percent solution of TEOS in humidified CO₂ at 90° C. and 125 bar for 3 hours. The reactor is then slowly vented to atmospheric pressure. The composite is then removed from the reactor.

### Example 15

### Using a Biodegradable Template Containing Additional Precursor

A sample of poly(DL-lactide) containing Ca(NO₃)₂ and a small amount of organic acid is prepared by injection molding to form a template for the structured material. The template is placed into a high-pressure reactor similar to that described in Example 1. The reactor is sealed and the film is exposed to a 0.1 percent solution of TEOS and tributyl phosphate in humidified CO₂ at 90° C. and 125 bar for 3 hours. The reaction deposits calcium phosphate and silica within the template. The reactor is then slowly vented to atmospheric pressure. The composite is then removed from the reactor.

### Example 16

### Infusion of a Block Copolymer Template in the Presence of a Master Followed by Detemplating and an E-Beam Cure

A poly(styrene-block-vinyl phenol) block copolymer is spin-coated from a solution containing a small amount of an organic acid. Upon drying, the block copolymer undergoes microphase separation and the acid partitions preferentially into the poly(vinyl phenol) block. The block copolymer template is patterned by hot embossing using a master. The master is held in place. The template in contact with the master is exposed to a solution of TEOS in humidified CO₂ at 75° C. and 150 bar for 30 minutes in a high pressure reactor. Condensation of TEOS occurs selectively in the acid-laden poly(vinyl phenol) block. The reactor is the slowly vented to atmospheric pressure. The polymer template is the removed by calcination at 400 C to yield a patterned mesoporous film on the wafer. The film is then cured in an ElectronCure E-beam flood exposure tool to increase the hardness of the film.

### Example 17

### Infusion of a Block Copolymer Template in the Presence of a Master Followed by an E-Beam Cure and Detemplating by Calcination

A poly(propylene oxide-block-polyethylene oxide) block copolymer is spin-coated from a solution containing a small amount of an organic acid. Upon drying, the block copolymer undergoes microphase separation and the acid partitions preferentially into the poly(ethylene oxide) block. The block copolymer template is patterned by hot embossing using a master. The master is held in place. The template in contact with the master is exposed to a solution of TEOS in humidified CO₂ at 75° C. and 150 bar for 30 minutes in a high pressure reactor. Condensation of TEOS occurs selectively in the acid-laden poly(vinyl phenol) block. The reactor is the slowly vented to atmospheric pressure. The film is then cured in an Electron Cure E-beam flood exposure tool to increase the hardness of the film. The polymer template is the removed by calcination at 400° C. to yield a patterned mesoporous film on the wafer.

### Example 18

### Infusion of a Block Copolymer Template Followed by an E-Beam Cure and Detemplating by Calcination

A poly(propylene oxide-block-polyethylene oxide) block copolymer is spin-coated from a solution containing a small amount of an organic acid. Upon drying, the block copolymer undergoes microphase separation and the acid partitions preferentially into the poly(ethylene oxide) block. The template is exposed to a solution of TEOS in humidified CO₂ at 75° C. and 150 bar for 30 minutes in a high pressure reactor. Condensation of TEOS occurs selectively in the acid-laden poly(vinyl phenol) block. The reactor is the slowly vented to atmospheric pressure. The film is then cured in an Electron Cure E-beam flood exposure tool to increase the hardness of the film. The polymer template is the removed by calcination at 400° C. to yield a patterned mesoporous film on the wafer.

### Other Embodiments

It is to be understood that while the invention has been described in conjunction with the detailed description thereof, the foregoing description is intended to illustrate and not limit the scope of the invention, which is defined by the scope of the intended claims. Other aspects, advantages, and modifications are within the scope of the following claims.

1. A method for forming a structured material, the method comprising:
providing a layer comprising a first material;
patterning the layer while at least a portion of a surface of the layer is not covered with a processing layer;
permeating the patterned layer with a precursor; and
reacting the precursor within the patterned layer to form the structured material.

2. The method of claim 1, wherein patterning the layer comprises exposing the layer to radiation.

3. The method of claim 2, wherein exposing the layer to radiation decomposes portions of the first material.

4. The method of claim 2, wherein exposing the layer to radiation crosslinks portions of the first material.

5. The method of claim 2, further comprising contacting the surface of the layer with a master while exposing the layer to radiation.

6. The method of claim 1, further comprising contacting the patterned layer with a master while permeating the patterned layer with a precursor.

7. The method of claim 1, wherein the layer is patterned by photolithography, step-and-flash lithography, or two-photon lithography.

8. The method of claim 1, wherein patterning the layer comprises imprinting the surface with a pattern.

9. The method of claim 8, wherein the layer is patterned by hot embossing.

10. The method of claim 8, wherein patterning the layer further comprises etching portions of the layer after the imprinting.

11. The method of claim 8, wherein the layer is patterned by imprint lithography.

12. The method of claim 1, wherein the patterned layer is permeated with a precursor delivery agent containing the precursor.

13. The method of claim 12, wherein the precursor delivery agent is a supercritical or near-supercritical fluid.

14. The method of claim 1, wherein the structured material is a nonporous material.

15. The method of claim 1, wherein the structured material is a porous material.

16. The method of claim 1, further comprising removing the first material after reacting the precursor within the patterned template.

17. The method of claim 16, wherein removing the first material comprises decomposing the first material.

18. The method of claim 17, wherein removing the first material further comprises extracting the decomposed material.

19. The method of claim 17, wherein decomposing the first material comprises heating the first material, exposing the first material to a solvent, or exposing the first material to radiation.

20. The method of claim 1, further comprising exposing the patterned layer to radiation.

21. The method of claim 20, wherein the patterned layer is exposed to radiation prior to permeating the patterned layer with a precursor.

22. The method of claim 20, wherein the patterned layer is exposed to additional radiation after permeating the patterned layer with a precursor.

23. The method of claim 1, wherein the first material is a homogeneous material.

24. The method of claim 1, wherein the first material is an inhomogeneous material.

25. The method of claim 1, wherein the first material comprises a monomer or polymer.

26. The method of claim 25, wherein the polymer comprises a copolymer.

27. A method for forming a structured material, the method comprising:
providing a layer comprising a first material;
exposing the layer to radiation to pattern the layer;
permeating the patterned layer with a precursor; and
reacting the precursor within the patterned layer to form the structured material.

28. A method for forming a structured material, the method comprising:
providing a layer comprising a first material;
imprinting a surface of the layer with a pattern;
permeating the layer with a precursor; and
reacting the precursor within the layer to form a structured material.

29. The method of claim 28, wherein imprinting the layer comprises contacting the layer with a master.

30. A method for forming a structured material, the method comprising:
forming a layer of a first material by surface photografting;
permeating the layer with a precursor; and
reacting the precursor within the template to form a structured material.

31. The method of claim 30, wherein the layer of the first material is a patterned layer.

32. The method of claim 30, wherein the surface photografting comprises reacting a polymer with a substrate to form an anchored polymer layer.

33. The method of claim 30, wherein the surface photografting comprises diffusing a monomer into a substrate surface.

34. The method of claim 33, wherein the substrate surface comprises an initiating or propagating species.

35. A method for forming a structured material, the method comprising:
providing a layer of a first material comprising a chiral moiety;
permeating the layer with a precursor; and
reacting the precursor within the layer to form the structured material.

36. The method of claim 35, wherein the first material comprises a side-chain liquid crystal polymer.

37. The method of claim 35, wherein the structured material comprises a biopolymer.

38. The method of claim 35, wherein the structured material comprises a peptide or a protein.
